(19) United States
(12) Patent Application Publication
(10) Pub. No.: US 2025/0374732 A1
(43) Pub. Date: Dec. 4, 2025

(54) DISPLAY DEVICE AND METHOD OF FABRICATING THE SAME

(71) Applicant: Samsung Display Co., LTD., Yongin-si (KR)

(72) Inventor: Ki Su JIN, Yongin-si (KR)

(73) Assignee: Samsung Display Co., LTD., Yongin-si (KR)

(21) Appl. No.: 19/006,618

(22) Filed: Dec. 31, 2024

(30) Foreign Application Priority Data
May 29, 2024 (KR) 10-2024-0069805

(51) Int. Cl. H10H 29/49; H10H 29/01

(52) U.S. Cl. CPC H10H 29/49; H10H 29/012

(57) ABSTRACT

A method of fabricating a display device may include providing a substrate, forming an insulating layer on the substrate, forming a first electrode layer on the insulating layer, and applying a photoresist to cover the insulating layer and the first electrode layer. The method may further include exposing the photoresist, forming a bonding layer on the first electrode layer by developing the photoresist, bonding a light emitting element to the bonding layer, and etching the insulating layer.

### CROSS-REFERENCE TO RELATED APPLICATION(S)

This application claims priority to and benefits of Korean patent application number 10-2024-0069805 under 35 U.S.C. § 119, filed on May 29, 2024 in the Korean Intellectual Property Office, the entire contents of which are incorporated herein by reference.

### BACKGROUND

### 1. Technical Field

Various embodiments of the disclosure relate to a display device and a method of manufacturing the display device.

### 2. Description of the Related Art

With the development of information technology, the importance of a display device that is a connection medium between a user and information has been emphasized. Owing to the importance of the display device, the use of various display devices such as a liquid crystal display device, an organic light emitting display device, and an inorganic light emitting display device has increased. Recently, research on micro LEDs, which are capable of realizing faster response time and higher luminance compared to existing LEDs, has been actively conducted.

### SUMMARY

Various embodiments of the disclosure are directed to a method of fabricating a display device capable of reducing defects due to short-circuits.

Various embodiments of the disclosure are directed to a method of fabricating a display device capable of increasing reflectance of light emitted from a light emitting element.

Various embodiments of the disclosure are directed to a display device fabricated by the display device fabrication method.

An embodiment of the disclosure may provide a method of fabricating a display device. The method may include providing a substrate, forming an insulating layer on the substrate, forming a first electrode layer on the insulating layer, applying a photoresist to cover the insulating layer and the first electrode layer, exposing the photoresist, forming a bonding layer on the first electrode layer by developing the photoresist, bonding a light emitting element to the bonding layer, and etching the insulating layer.

In an embodiment, the etching of the insulating layer may be by dry etching.

In an embodiment, the etching of the insulating layer may be by spraying an etching material onto an overall area of the substrate.

In an embodiment, the etching of the insulating layer may include etching the bonding layer using the light emitting element as a mask.

In an embodiment, the bonding of the light emitting element to the bonding layer may include bonding a plurality of light emitting elements including the light emitting element to the bonding layer. The etching of the insulating layer may include etching the bonding layer between the light emitting elements.

In an embodiment, the photoresist may include a conductive material.

In an embodiment, the photoresist may include carbon black.

In an embodiment, the light emitting element may further include a semiconductor layer, and an auxiliary layer disposed on the semiconductor layer.

In an embodiment, the auxiliary layer may include an undoped semiconductor material.

In an embodiment, the first electrode layer may include at least one of aluminum (Al), silver (Ag), magnesium (Mg), platinum (Pt), palladium (Pd), gold (Au), nickel (Ni), neodymium (Nd), iridium (Ir), chromium (Cr), and titanium (Ti).

In an embodiment, the method may further include forming a second electrode layer on the light emitting element.

In an embodiment, the first electrode layer may include a first electrode connected to the light emitting element, and a second electrode spaced apart from the first electrode.

In an embodiment, the method may further include, forming a bank on the insulating layer, and forming a reflective layer on a side surface of the bank.

An embodiment of the disclosure may provide a method of fabricating a display device. The method may include providing a substrate, forming an insulating layer on the substrate, forming an electrode layer on the insulating layer, applying a photoresist to cover the insulating layer and the electrode layer, exposing the photoresist, forming a bonding layer on the electrode layer by developing the photoresist, bonding light emitting elements to the bonding layer, and etching the bonding layer between the light emitting elements.

In an embodiment, the etching of the bonding layer may be by dry etching.

In an embodiment, the etching of the bonding layer may be by spraying an etching material onto an overall area of the substrate.

In an embodiment, the etching of the bonding layer may use the light emitting elements as a mask.

In an embodiment, the photoresist may include a conductive material.

An embodiment of the disclosure may provide a display device. The display device may include a substrate, an insulating layer disposed on the substrate, an overcoat layer disposed on a first portion of the insulating layer, an electrode layer disposed on a second portion of the insulating layer, a bonding layer disposed on the electrode layer, and a light emitting element bonded to the bonding layer. A height of the first portion of the insulating layer may be less than a height of the second portion of the insulating layer.

In an embodiment, the light emitting element may be one among a plurality of light emitting elements bonded to the bonding layer. The electrode layer may be exposed between the light emitting elements.

### BRIEF DESCRIPTION OF THE DRAWINGS

FIG. 1 is a schematic block diagram illustrating an embodiment of a display device.

FIG. 2 is a schematic block diagram illustrating an embodiment of any one of sub-pixels of FIG. 1.

FIG. 3 is a schematic plan view illustrating an embodiment of a display panel of FIG. 1.

FIG. 4 is a schematic sectional view illustrating an embodiment of the display panel of FIG. 3.

FIG. 5 is a schematic sectional view illustrating another embodiment of the display panel of FIG. 3.

FIG. 6 is a schematic plan view illustrating an embodiment of any one of the pixels of FIG. 3.

FIG. 7 is a schematic sectional view taken along line X-X′ of FIG. 6.

FIG. 8 is a schematic sectional view taken along line Y-Y′ of FIG. 6;

FIG. 9 is a schematic flowchart illustrating a method of fabricating the display device in accordance with embodiments of the disclosure.

FIGS. 10 to 15 are schematic views for describing the display device fabrication method of FIG. 9.

FIG. 16 is a schematic view illustrating another embodiment of a sectional view taken along line X-X′ of FIG. 6.

FIG. 17 is a schematic plan view illustrating another embodiment of any one of the pixels of FIG. 3.

FIG. 18 is a schematic plan view illustrating an embodiment of any one of pixels of the display device in accordance with embodiments of the disclosure.

FIG. 19 is a schematic sectional view taken along line I-I′ of FIG. 18.

FIG. 20 is a schematic sectional view taken along line II-II′ of FIG. 18.

FIG. 21 is a schematic block diagram illustrating an embodiment of a display system.

FIGS. 22 to 25 are schematic perspective views illustrating application examples of the display system of FIG. 21.

### DETAILED DESCRIPTION OF THE EMBODIMENTS

Hereinafter, embodiments of the disclosure will be described in detail with reference to the attached drawings. In the following description, only parts required for understanding of operations in accordance with the disclosure will be described, and explanation of the other parts will be omitted not to make the gist of the disclosure unclear. Accordingly, the disclosure is not limited to the embodiments set forth herein but may be embodied in other forms. These embodiments are provided so that the disclosure will be thorough and complete, and will fully convey the technical spirit of the disclosure to those skilled in the art.

As used herein, the singular forms, “a,” “an,” and “the” are intended to include the plural forms as well, unless the context clearly indicates otherwise.

It will be understood that when an element is referred to as being “coupled” or “connected” to another element, it can be directly coupled or connected to the other element or intervening elements may be present therebetween. The terminology used herein is for the purpose of describing particular embodiments only and is not intended to be limiting. In the specification, when an element is referred to as “comprising,” “having,” or “including” a component, it does not preclude another component but may further include other components unless the context clearly indicates otherwise. The construction “at least one of X, Y, and Z” and “at least one selected from the group consisting of X, Y, and Z” may be construed as X only, Y only, Z only, or any combination of two or more of X, Y, and Z (for instance, XYZ, XYY, YZ, and ZZ). As used herein, the term “and/or” can include any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein can be interpreted accordingly.

Herein, various embodiments will be described with reference to drawings that are schematic illustrations of idealized embodiments. As such, variations from the shapes of the illustrations as a result, for example, of manufacturing techniques and/or tolerances, are to be expected. Therefore, embodiments disclosed herein should not be construed as limited to the particular illustrated shapes of regions, but are to include deviations in shapes that result from, for instance, manufacturing. As such, the shapes illustrated in the drawings may not illustrate the actual shapes of regions of a device, and, as such, are not intended to be limiting.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

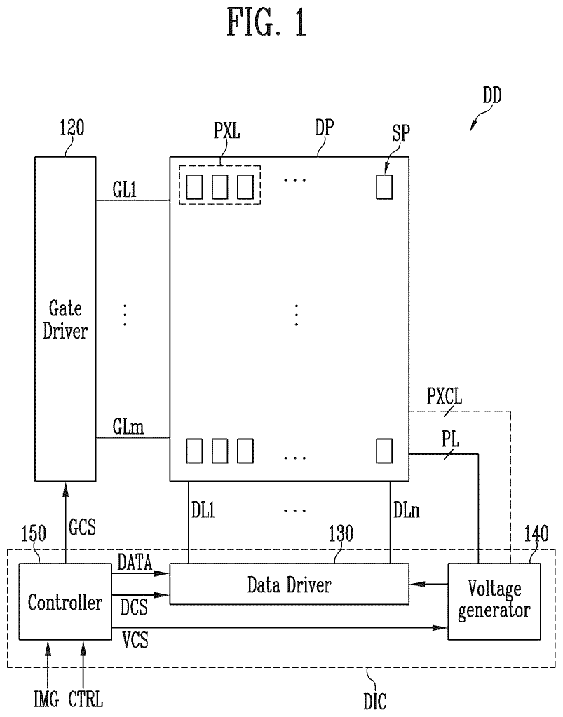

FIG. 1 is a schematic block diagram illustrating an embodiment of a display device DD.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light in two or more colors. For example, each of the sub-pixels SP may generate light in a color such as red, green, blue, cyan, magenta, or yellow.

Two or more sub-pixels among the sub-pixels SP may form a pixel PXL. For example, the pixel PXL may include three sub-pixels, as illustrated in FIG. 1. As such, the pixel PXL may emit light of various colors and various luminances depending on the combination of light emitted from the sub-pixels included therein.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. In embodiments, the gate control signal GCS may include a start signal instructing each frame to start, a horizontal synchronization signal, and the like.

The gate driver 120 may be disposed on a side of the display panel DP. However, embodiments are not limited to the aforementioned example. For example, the gate driver 120 may be divided into two or more drivers that are physically and/or logically distinguished from each other. The drivers may be disposed on a first side of the display panel DP and a second side of the display panel DP opposite to the first side. As such, the gate driver 120 may be disposed around the display panel DP in various forms depending on the embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may apply, using received voltages, data signals having grayscale voltages corresponding to the image data DATA to the first to n-th data lines DL1 to DLn. In case that a gate signal is applied to each of the first to m-th gate lines GL1 to GLm, data signals corresponding to the image data DATA may be applied to the data lines DL1 to DLn. Hence, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 may be configured to generate voltages and provide the generated voltages to components of the display device DD such as the gate driver 120, the data driver 130, and the controller 150. The voltage generator 140 may receive an input voltage from an external device of the display device DD and generate voltages by regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from an external device to the display device DD.

The voltage generator 140 may provide various voltages and/or signals. For example, the voltage generator 140 may provide one or more initialization voltages to be applied to the sub-pixels SP. For example, during a sensing operation for sensing electrical characteristics of transistors and/or light emitting elements of the sub-pixels SP, a certain reference voltage may be applied to each of the first to n-th data lines DL1 to DLn. The voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through pixel control lines PXCL. Although in FIG. 1 there is illustrated the case where the pixel control lines PXCL are connected between the voltage generator 140 and the display panel DP, the embodiments are not limited thereto. For example, the pixel control lines PXCL may be connected between the gate driver 120 and the display panel DP. The pixel control signals may be transmitted from the voltage generator 140 to the pixel control lines PXCL through the gate driver 120.

The controller 150 may control overall operations of the display device DD. The controller 150 may receive input image data IMG and a control signal CTRL corresponding thereto from an external device. The controller 150 may provide a gate control signal GCS, a data control signal DCS, and a voltage control signal VCS, in response to the control signal CTRL.

The controller 150 may convert the input image data IMG to be suitable for the display device DD or the display panel DP and output image data DATA. In embodiments, the controller 150 may align the input image data IMG to be suitable for the sub-pixels SP on a row basis and output the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. The data driver 130, the voltage generator 140, and the controller 150 may be components that are functionally separated from each other in the single driver integrated circuit DIC. In other embodiments, at least one of the data driver 130, the voltage generator 140, and the controller 150 may be provided as a component separated from the driver integrated circuit DIC.

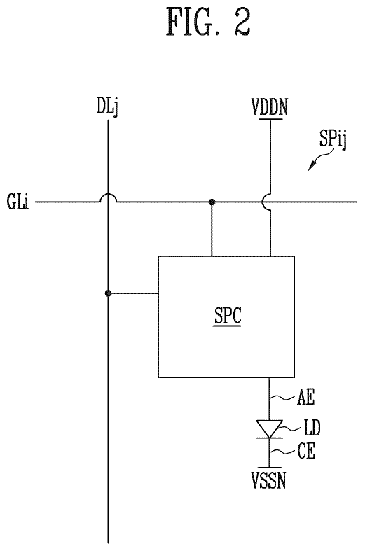

FIG. 2 is a schematic block diagram illustrating an embodiment of any one of sub-pixels of FIG. 1. In FIG. 2, a sub-pixel SPij is illustrated, disposed on an i-th row (where i is an integer equal to or greater than 1 and less than or equal to m) and a j-th column (where j is an integer equal to or greater than 1 and less than or equal to n) among the sub-pixels SP of FIG. 1.

Referring to FIG. 2, the sub-pixel SPij may include a sub-pixel circuit SPC and a light emitting element LD.

The light emitting element LD is connected between a first power voltage node VDDN and a second power voltage node VSSN. The first power voltage node VDDN may be connected to at least one of the power lines PL of FIG. 1 to receive a first power voltage. The second power voltage node VSSN may be connected to at least another one of the power lines PL of FIG. 1 to receive a second power voltage. The first power voltage may have a voltage level higher than the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light based on current flowing from the anode electrode AE to the cathode electrode CE.

The sub-pixel circuit SPC may be connected both to the i-th gate line GLi among the first to m-th gate lines GL1 to GLm of FIG. 1 and to the j-th data line DLj among the first to n-th data lines DL1 to DLn of FIG. 1. In response to a gate signal received through the i-th gate line GLi, the sub-pixel circuit SPC may control the light emitting element LD to emit light based on a data signal received through the j-th data line DLj. In embodiments, the sub-pixel circuit SPC may be further connected to the pixel control lines PXCL of FIG. 1. The sub-pixel circuit SPC may further control the light emitting element LD in response to pixel control signals received through the pixel control lines PXCL.

For the sake of the aforementioned operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, or the like.

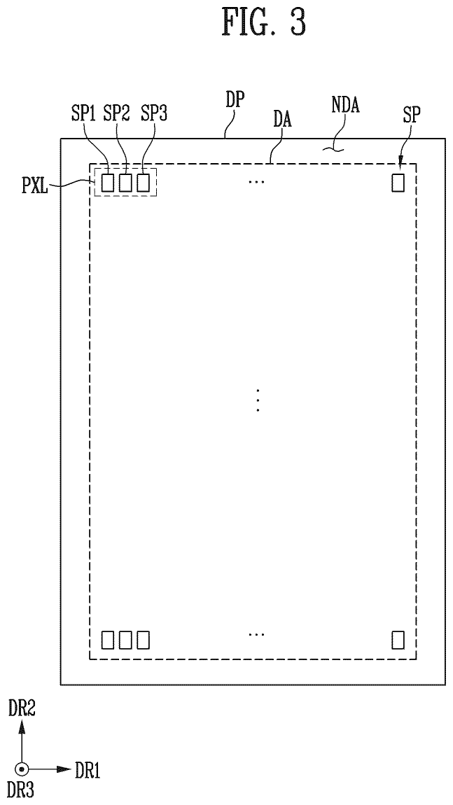

FIG. 3 is a schematic plan view illustrating an embodiment of the display panel DP of FIG. 1.

Referring to FIG. 3, the display panel DP may include a display area DA and a non-display area NDA. The display panel DP may display an image through the display area DA. The non-display area NDA may be disposed around the display area DA.

The display panel DP may include sub-pixels SP in the display area DA. The sub-pixels SP may be arranged in a first direction DR1 and a second direction DR2 intersecting with the first direction DR1. For example, the sub-pixels SP may be arranged in the form of a matrix in the first direction DR1 and the second direction DR2. As another example, the sub-pixels SP may be arranged in a zigzag form in the first direction DR1 and the second direction DR2. The arrangement of the sub-pixels SP may be changed depending on embodiments. The first direction DR1 may refer to a row direction, and the second direction DR2 may refer to a column direction.

Two or more sub-pixels among the sub-pixels SP may form a pixel PXL. Although FIG. 3 illustrates that the pixel PXL includes three sub-pixels SP1 to SP3, the embodiments are not limited thereto. For example, the pixel PXL may include two sub-pixels. Hereinafter, for convenience of explanation, it is assumed that the pixel PXL includes first to third sub-pixels SP1 to SP3.

Each of the first to third sub-pixels SP1 to SP3 may generate light of one or more among various colors such as red, green, blue, cyan, magenta, and yellow. Hereinafter, for clear and concise description, it is assumed that the first sub-pixel SP1 is configured to generate light in red, the second color pixel SP2 is configured to generate light in green, and the third sub-pixel SP3 is configured to generate light in blue.

Each of the first to third sub-pixels SP1 to SP3 may include at least one light emitting element configured to generate light. In embodiments, the light emitting elements of the first to third sub-pixels SP1 to SP3 may generate light in the same color. For example, the light emitting elements of the first to third sub-pixels SP1 to SP3 may generate light in blue. In other embodiments, the light emitting elements of the first to third sub-pixels SP1 to SP3 may generate light in different colors. For example, the light emitting elements of the first to third sub-pixels SP1 to SP3 may respectively generate light in red, green, and blue.

As a display panel DP, a self-emissive display panel such as an LED display panel using a micro-scale or nano-scale light emitting diode as a light emitting element, and an organic light emitting display panel (OLED panel) using an organic light emitting diode as a light emitting element may be used.

Components for controlling the sub-pixels SP may be disposed in the non-display area NDA. Lines connected to the sub-pixels SP, for example, the first to m-th gate lines GL1 to GLm, the first to n-th data lines DL1 to DLn, the power lines PL, and the pixel control lines PXCL of FIG. 1, may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. The data driver 130, the voltage generator 140, and the controller 150 may be implemented as the driver integrated circuit DIC of FIG. 1 that is separated from the display panel DP. The driver integrated circuit DIC may be connected to the lines disposed in the non-display area NDA. In other embodiments, the gate driver 120 along with the data driver 130, the voltage generator 140, and the controller 150 may be implemented as a single integrated circuit that is separated from the display panel DP.

In embodiments, the display area DA may have various shapes. The display area DA may have a closed-loop shape, including linear and/or curved sides. For example, the display area DA may have shapes such as a polygon, a circle, a semicircle, and an ellipse.

In embodiments, the display panel DP may have a planar display surface. In embodiments, the display panel DP may have a display surface that is least partially rounded. In embodiments, the display panel DP may be bendable, foldable, or rollable. In the aforementioned cases, the display panel DP and/or a substrate of the display panel DP may include materials having flexible properties.

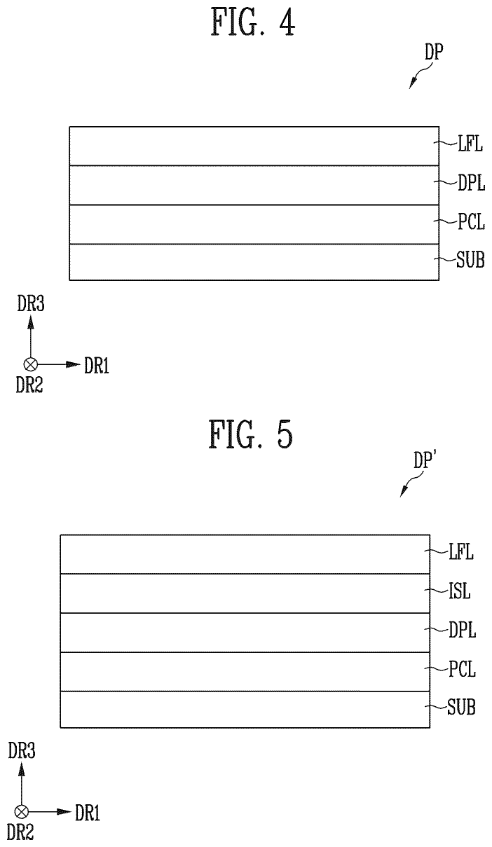

FIG. 4 is a schematic sectional view illustrating an embodiment of the display panel of FIG. 3.

Referring to FIG. 4, a display panel DP may include a substrate SUB, and a pixel circuit layer PCL, a display element layer DPL, and a light functional layer LFL that are stacked on each other on the substrate SUB in a third direction DR3 intersecting with the first and second directions DR1 and DR2.

The substrate SUB may be made of insulating material such as glass or resin. For example, the substrate SUB may include a glass substrate. As another example, the substrate SUB may include a polyimide (PI) substrate. As another example, the substrate SUB may include a silicon wafer substrate formed through a semiconductor process.

In embodiments, the substrate SUB may be made of material having flexibility so as to be bendable or foldable, and may have a single-layer structure or a multilayer structure. For instance, the material having flexibility may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the embodiments are not limited to the aforementioned examples.

The pixel circuit layer PCL may be disposed on the substrate SUB. The pixel circuit layer PCL may include insulating layers, and semiconductor patterns and conductive patterns disposed between the insulating layers. The conductive patterns of the pixel circuit layer PCL may function as circuit elements, lines, or the like.

The circuit elements of the pixel circuit layer PCL may include the respective sub-pixel circuits SPC (refer to FIG. 2) of the sub-pixels SP of FIG. 3. In other words, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines needed to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may convert the wavelength (or color) of light emitted from the display element layer DPL. The light functional layer LFL may further include light scattering patterns having scattering particles. In embodiments, the light conversion patterns and the light scattering patterns may be omitted.

The light functional layer LFL may further include a color filter layer including color filters. Each of the color filters may selectively transmit light of a specific wavelength (or specific color). In embodiments, the color filter layer may be omitted.

A window may be provided on the light functional layer LFL to protect an exposed surface (or upper surface) of the display panel DP. The window may protect the display panel DP from an external impact. The window may be connected to the light functional layer LFL by an optically transparent adhesive (or bonding) agent. The window may have a multilayer structure selected from among a glass substrate, a plastic film, and a plastic substrate. The multilayer structure may be formed through a successive process or an adhesion process using an adhesive layer. The entirety or portion of the window may have flexibility.

FIG. 5 is a schematic sectional view illustrating another embodiment of the display panel of FIG. 3.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured in the same manner as the substrate SUB, the pixel circuit layer PCL, the display element layer DPL, and the light functional layer LFL that have been described with reference to FIG. 4. Hereinafter, repetitive explanations will be omitted.

The input sensing layer ISL may sense a user input on an upper surface (or display surface) of the display panel DP'. The input sensing layer ISL may include components suitable for sensing an external object such as the hand of the user, a pen, or the like. For example, the input sensing layer ISL may include touch electrodes.

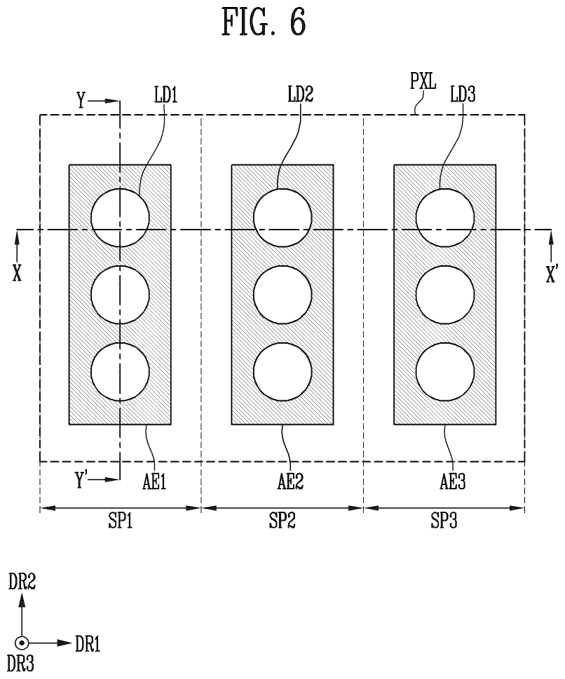

FIG. 6 is a schematic plan view illustrating an embodiment of any one of the pixels PXL of FIG. 3.

Referring to FIG. 6, the pixel PXL may include first to third sub-pixels SP1 to SP3. The first and third sub-pixels SP1 to SP3 may be arranged in the first direction DR1. However, the arrangement of the pixel PXL is not limited thereto, and may be changed in various ways depending on the embodiments. For example, the first to third sub-pixels SP1 to SP3 may be arranged in a zigzag pattern.

First to third anode electrodes AE1 to AE3 may be respectively disposed in the first to third sub-pixels SP1 to SP3. The first anode electrode AE1 may be provided as an anode electrode AE (refer to FIG. 2) included in the sub-pixel circuit SPC (refer to FIG. 2) of the first sub-pixel SP1. The second anode electrode AE2 may be provided as an anode electrode AE included in the sub-pixel circuit SPC of the second sub-pixel SP2. The third anode electrode AE3 may be provided as an anode electrode AE included in the sub-pixel circuit SPC of the third sub-pixel SP3.

First light emitting elements LD1, second light emitting elements LD2, and third light emitting elements LD3 may be respectively disposed on the first to third anode electrodes AE1 to AE3. The first light emitting elements LD1 may be connected to the first anode electrode AE1. The second light emitting elements LD2 may be connected to the second anode electrode AE2. The third light emitting elements LD3 may be connected to the third anode electrode AE3. In case that multiple light emitting elements are provided in each sub-pixel, each anode electrode may have a shape extending in a specific direction, e.g., the second direction DR2, and light emitting elements connected thereto may be arranged in the same direction.

The first light emitting elements LD1 may be provided as the light emitting element LD of FIG. 2 included in the first sub-pixel SP1. The second light emitting elements LD2 may be provided as the light emitting element LD of FIG. 2 included in the second sub-pixel SP2. The third light emitting elements LD3 may be provided as the light emitting element LD of FIG. 2 included in the third sub-pixel SP3. In case that multiple light emitting elements are provided in each sub-pixel, the light emitting elements may be connected in parallel between the anode electrode and the cathode electrode and thus provided as the light emitting element LD of FIG. 2.

The first light emitting elements LD1, the second light emitting elements LD2, and the third light emitting elements LD3 may be inorganic light emitting diodes including inorganic light emitting material. However, the embodiments are not limited to the aforementioned example and, for example, organic light emitting diodes may be used.

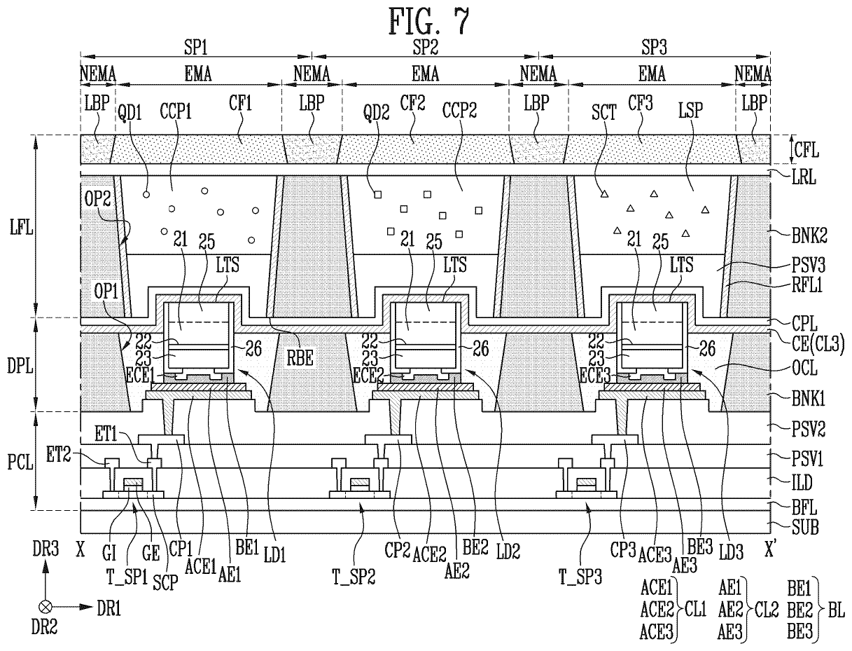

FIG. 7 is a schematic sectional view taken along line X-X′ of FIG. 6.

Referring to FIGS. 6 and 7, the pixel circuit layer PCL, the display element layer DPL, and the light functional layer LFL may be sequentially disposed on the substrate SUB.

The pixel circuit layer PCL may include insulating layers, semiconductor patterns, and conductive patterns that are stacked on the substrate SUB. The insulating layers may include a buffer layer BFL, one or more interlayer insulating layers ILD, and one or more passivation layers PSV1 and PSV2. The semiconductor patterns and the conductive patterns may be positioned between the insulating layers. The conductive patterns may include at least one material of copper (Cu), molybdenum (Mo), tungsten (W), aluminum-neodymium (AlNd), titanium (Ti), aluminum (Al), and silver (Ag).

As described with reference to FIG. 2, the sub-pixel circuit SPC (refer to FIG. 2) of each of the first to third sub-pixels SP1 to SP3 may include transistors and one or more capacitors. The semiconductor patterns and the conductive patterns of the pixel circuit layer PCL may function as the transistors and the capacitors of the sub-pixel circuit SPC. Furthermore, the conductive patterns of the pixel circuit layer PCL may also function as lines, for example, the first to m-th gate lines GL1 to GLm, the first to n-th data lines DL1 to DLn, the power lines PL, and the pixel control lines PXCL of FIG. 1.

The buffer layer BFL may be disposed on a surface of the substrate SUB. The buffer layer BFL may prevent impurities from diffusing into the circuit elements and the lines that are included in the pixel circuit layer PCL. The buffer layer BFL may include an inorganic insulating layer including inorganic material. In embodiments, the buffer layer BFL may include at least one of silicon nitride (SiNₓ), silicon oxide (SiOₓ), silicon oxynitride (SiOₓN_{y}), and metal oxide such as aluminum oxide (AlOₓ). The buffer layer BFL may be provided in the form of a single layer or multiple layers. In case that the buffer layer BFL is provided in the form of a multilayer structure, the respective layers may be formed of the same material or different materials.

In embodiments, one or more barrier layers may be disposed between the substrate SUB and the buffer layer BFL. Each of the barrier layers may include polyimide.

First to third transistors T_SP1 to T_SP3 corresponding to the first to third sub-pixels SP1 to SP3, respectively, may be disposed on the buffer layer BFL. The first transistor T_SP1 may be any of the transistors of the sub-pixel circuit SPC included in the first sub-pixel SP1. The second transistor T_SP2 may be any of the transistors of the sub-pixel circuit SPC included in the second sub-pixel SP2. The third transistor T_SP3 may be any of the transistors of the sub-pixel circuit SPC included in the third sub-pixel SP3. Each of the first to third transistors T_SP1 to T_SP3 may be understood as a transistor connected to the anode electrode among the transistors of the corresponding sub-pixel.

The first transistor T_SP1 may include a semiconductor pattern SCP, a gate electrode GE, a first terminal ET1, and a second terminal ET2. The first terminal ET1 may be either a source electrode or a drain electrode, and the second terminal ET2 may be a remaining one of the source electrode and the drain electrode. For example, the first terminal ET1 may be a source electrode, and the second terminal ET2 may be a drain electrode.

The semiconductor pattern SCP may be disposed on the buffer layer BFL. The semiconductor pattern SCP may include a first contact area that contacts the first terminal ET1, and a second contact area that contacts the second terminal ET2. An area between the first contact area and the second contact area may be a channel area. The channel area may overlap the gate electrode GE of the first transistor T_SP1. The channel area may be an undoped semiconductor pattern, and may be an intrinsic semiconductor. Each of the first contact area and the second contact area may be a semiconductor pattern doped with an impurity. For example, a p-type impurity may be used as the impurity, but the embodiments are not limited thereto.

The semiconductor pattern SCP may include any of various types of semiconductors, for example, an amorphous silicon semiconductor, a monocrystalline silicon semiconductor, a polycrystalline silicon semiconductor, a low temperature poly silicon semiconductor, and an oxide semiconductor.

The interlayer insulating layers ILD that are stacked on each other may be disposed on the semiconductor pattern SCP. The interlayer insulating layers ILD may be formed of inorganic insulating layers including inorganic material. For example, each of the interlayer insulating layers ILD may include at least one of silicon nitride (SiNₓ), silicon oxide (SiOₓ), silicon oxynitride (SiOₓN_{y}), and metal oxide such as aluminum oxide (AlOₓ). However, the material of the interlayer insulating layers ILD is not limited to the aforementioned examples. For example, any of the interlayer insulating layers ILD may include an organic insulating layer including organic material.

The interlayer insulating layers ILD may electrically separate the conductive patterns and/or semiconductor patterns that are disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE such that the semiconductor pattern SCP is spaced apart from the gate electrode GE. In embodiments, the gate insulating layer GI may be disposed on the overall surfaces of the semiconductor pattern SCP and the buffer layer BFL, thus covering the semiconductor pattern SCP and the buffer layer BFL. As the number of layers needed to form the conductive patterns and/or the semiconductor layers increases, the number of interlayer insulating layers ILD may increase.

The gate electrode GE may be disposed on the gate insulating layer GI. The gate electrode GE may overlap the channel area of the semiconductor pattern SCP. In embodiments, the gate electrode GE may be provided in the form of a single layer including at least one material of copper (Cu), molybdenum (Mo), tungsten (W), aluminum-neodymium (AlNd), titanium (Ti), aluminum (Al), and silver (Ag). In embodiments, the gate electrode GE may be provided in the form of a multilayer structure including at least one material of molybdenum (Mo), titanium (Ti), aluminum (Al), and silver (Ag) that are low-resistance materials.

The first and second terminals ET1 and ET2 may be disposed on the interlayer insulating layers ILD. The first and second terminals ET1 and ET2 may contact the semiconductor pattern SCP through contact holes passing through the interlayer insulating layers ILD. The first and second terminals ET1 and ET2 may respectively contact the first and second contact areas of the semiconductor pattern SCP. Each of the first and second terminals ET1 and ET2 may include at least one material of copper (Cu), molybdenum (Mo), tungsten (W), aluminum-neodymium (AlNd), titanium (Ti), aluminum (Al), and silver (Ag).

Although the first and second terminals ET1 and ET2 are illustrated as separate electrodes electrically connected to the semiconductor pattern SCP, the embodiments are not limited thereto. In embodiments, the first terminal ET1 may be a first contact area adjacent to a side of the channel area of the semiconductor pattern SCP, and the second terminal ET2 may be a second contact area adjacent to another side of the channel area. The first terminal ET1 may be electrically connected to the light emitting element LD through a connector such as a bridge electrode disposed on at least one of the interlayer insulating layers ILD.

In embodiments, the first transistor T_SP1 may be formed of a low-temperature polysilicon transistor. However, embodiments are not limited to the aforementioned example. For example, the first transistor T_SP1 may be formed of an oxide semiconductor transistor. In embodiments, the sub-pixel circuit of each sub-pixel may include different types of transistors. For example, the first transistor T_SP1 may be formed of a low-temperature polysilicon transistor. Other transistors of the first sub-pixel SP1 may be formed of oxide semiconductor transistors. An oxide semiconductor of the corresponding oxide semiconductor transistor may be disposed on any of the interlayer insulating layers ILD rather than on an insulating layer on which the semiconductor pattern SCP of the first transistor T_SP1 is disposed.

Although in the embodiments the case where the first transistor T_SP1 has a top gate structure has been described as an example, the embodiments are not limited thereto. For example, the first transistor T_SP1 may be a transistor having a bottom gate structure. The structure of the first transistor T_SP1 may be changed in various ways.

Each of the second and third transistors T_SP2 and T_SP3 may be configured in the same manner as the first transistor T_SP1. Hereinafter, repetitive explanations will be omitted.

At least some of the various lines for the display panel DP and/or the display device DD may be further disposed on the interlayer insulating layers ILD.

The first passivation layer PSV1 may be disposed on the first to third transistors T_SP1 and T_SP3. The passivation layer may also be referred to as a protective layer or a via layer. The first passivation layer PSV1 may protect components disposed thereunder and provide an even upper surface.

First to third connection patterns CP1 to CP3 may be disposed on the first passivation layer PSV1. The first to third connection patterns CP1 to CP3 may pass through the first passivation layer PSV1 and be respectively connected to the first terminals ET1 of the first to third transistors T_SP1 to T_SP3. Each of the first to third connection patterns CP1 to CP3 may include at least one material of copper (Cu), molybdenum (Mo), tungsten (W), aluminum-neodymium (AlNd), titanium (Ti), aluminum (Al), and silver (Ag).

At least some of the various lines for the display panel DP and/or the display device DD may be further disposed on the first passivation layer PSV1.

The second passivation layer PSV2 may be disposed on the first to third connection patterns CP1 to CP3 and the first passivation layer PSV1. The first passivation layer PSV1 may protect components disposed thereunder and provide an even upper surface.

Each of the first and second passivation layers PSV1 and PSV2 may include an inorganic insulating layer including inorganic material, and/or an organic insulating layer including organic material. The inorganic insulating layer may include, for example, at least one of silicon oxide (SiOₓ), silicon nitride (SiNₓ), silicon oxynitride (SiOₓN_{y}), and metal oxide such as aluminum oxide (AlOₓ). The organic insulating layer may include, for example, at least one of acrylic resin, epoxy resin, phenol resin, polyamide resin, polyimide rein, unsaturated polyester resin, poly-phenylen ether resin, poly-phenylene sulfide resin, and benzocyclobutene resin.

The first and second passivation layers PSV1 and PSV2 may include the same material as any of the interlayer insulating layers ILD, but the embodiments are not limited thereto. Each of the first and second passivation layers PSV1 and PSV2 may be provided in the form of a single-layer structure, but may be provided in the form of a multilayer structure.

The display element layer DPL may be disposed on the second passivation layer PSV2. The display element layer DPL may include a first electrode layer CL1, a second electrode layer CL2, a bonding layer BL, a first bank BNK1, the first to third light emitting elements LD1 to LD3, an overcoat layer OCL, a third electrode layer CL3, and a capping layer CPL. The first electrode layer CL1 may include first to third anode connection electrodes ACE1 to ACE3. The second electrode layer CL2 may include the first to third anode electrodes AE1 to AE3. The bonding layer BL may include first to third bonding electrodes BE1 to BE3. The third electrode layer CL3 may include the cathode electrode CE.

The overcoat layer OCL may be disposed on a first portion of the second passivation layer PSV2. The first and second electrode layers CL1 and CL2 may be disposed on a second portion of the second passivation layer PSV2. A height of the first portion of the second passivation layer PSV2 may be less than that of the second portion of the second passivation layer PSV2. Details pertaining to the foregoing will be provided later herein.

On the pixel circuit layer PCL, the first to third anode connection electrodes ACE1 to ACE3 and the first to third anode electrodes AE1 to AE3 may be respectively disposed in the first to third sub-pixels SP1 to SP3.

The first anode connection electrode ACE1 may be electrically connected to the first connection pattern CP1 through a contact hole passing through the second passivation layer PSV2. The second anode connection electrode ACE2 may be electrically connected to the second connection pattern CP2 through another contact hole passing through the second passivation layer PSV2. The third anode connection electrode ACE3 may be electrically connected to the third connection pattern CP3 through another contact hole passing through the second passivation layer PSV2. The first anode electrode AE1 may be electrically connected to the first anode connection electrode ACE1. The second anode electrode AE2 may be electrically connected to the second anode connection electrode ACE2. The third anode electrode AE3 may be electrically connected to the third anode connection electrode ACE3. As such, the first to third anode electrodes AE1 to AE3 may be respectively electrically connected to the first to third transistors T_SP1 to T_SP3.

In an embodiment, an example is illustrated where the first to third anode electrodes AE1 to AE3 are respectively electrically connected to the first to third transistors T_SP1 to T_SP3 through the first to third anode connection electrodes ACE1 to ACE3. However, the disclosure is not limited to the foregoing example. For example, the first to third anode electrodes AE1 to AE3 may be directly connected to the first to third transistors T_SP1 to T_SP3.

The second electrode layer CL2 including the first to third anode electrodes AE1 to AE3 may be made of conductive material with a certain reflectivity. The conductive material may include opaque metal. For example, the opaque metal may include metal such as silver (Ag), magnesium (Mg), aluminum (Al), platinum (Pt), palladium (Pd), gold (Au), nickel (Ni), neodymium (Nd), iridium (Ir), chrome (Cr), titanium (Ti), and an alloy thereof. However, the material of the first to third anode electrodes AE1 to AE3 is not limited to the aforementioned examples.

Since each of the first to third anode electrodes AE1 to AE3 has a certain reflectivity, the first to third anode electrodes AE1 to AE3 may reflect light emitted from the first to third light emitting elements LD1 to LD3. Consequently, the light output efficiency of the first to third light emitting elements LD1 to LD3 may be enhanced.

The first bank BNK1 may be disposed on the second passivation layer PSV2. The first bank BNK1 may include first openings OP1 through which at least portions of the first to third anode electrodes AE1 to AE3 are exposed. The first to third light emitting elements LD1 to LD3 may be disposed in the first openings OP1 of the first bank BNK1. As such, the first bank BNK1 may be provided as a pixel defining layer that defines areas where the first to third light emitting elements LD1 to LD3 are positioned.

The first bank BNK1 may include light blocking material to prevent light mixing between adjacent sub-pixels. In embodiments, the first bank BNK1 may include organic material. For example, the first bank BNK1 may include organic insulating material made of material such as acryl resin, epoxy resin, phenol resin, polyamide resin, polyimide resin, or the like.

The first to third light emitting elements LD1 to LD3 may be respectively disposed on the first to third anode electrodes AE1 to AE3. The first to third bonding electrodes BE1 to BE3 may be disposed on the first to third anode electrodes AE1 to AE3. The first to third light emitting elements LD1 to LD3 may be bonded to the first to third bonding electrodes BE1 to BE3 and thus electrically connected to the first to third anode electrodes AE1 to AE3.

The bonding layer BL including the first to third bonding electrodes BE1 to BE3 may include conductive material. For example, the bonding layer BL may include carbon black.

The first light emitting element LD1 may include a first light-emitting-element connection electrode ECE1, a first semiconductor layer 21, an active layer 22, a second semiconductor layer 23, and an auxiliary layer 25. The first light emitting element LD1 may be implemented as a vertical emission stack in which the first light-emitting-element connection electrode ECE1, the second semiconductor layer 23, the active layer 22, the first semiconductor layer 21, and the auxiliary layer 25 are stacked on each other in the third direction DR3.

The first semiconductor layer 21 may be configured to provide electrons. The first semiconductor layer 21 may include, for example, at least one n-type semiconductor layer. For example, the first semiconductor layer 21 may include at least one semiconductor material among gallium nitride (GaN), aluminum gallium nitride (AlGaN), indium gallium nitride (InGaN), aluminum nitride (AlN), and indium nitride (InN), and may be an n-type semiconductor layer doped with a first conductive dopant (or n-type dopant) such as silicon (Si), germanium (Ge), or tin (Sn). However, the material for forming the first semiconductor layer 21 is not limited to the aforementioned example, and various other materials may be used to form the first semiconductor layer 21. In an embodiment of the disclosure, the first semiconductor layer 21 may include gallium nitride (GaN) semiconductor material doped with a first conductive dopant (or an n-type dopant). In an embodiment, the first semiconductor layer 21 along with the auxiliary layer 25 may form an n-type semiconductor layer.

The active layer 22 may be disposed on the first semiconductor layer 21, and may be an area where electrons and holes are recombined with each other. As electrons and holes are recombined with each other in the active layer 22, the electrons and holes make a transition to a low energy level, thereby generating light having a corresponding wavelength. The active layer 22 may have a single or multi-quantum well structure. In case that the active layer 22 is formed to have a multi-quantum well structure, units each including a barrier layer, a stain reinforcing layer, and a well layer may be repeatedly stacked to form the active layer 22. However, embodiments of the active layer 22 are not limited to the aforementioned example.

The second semiconductor layer 23 may be disposed on the active layer 22, and may provide holes to the active layer 22. The second semiconductor layer 23 may include a semiconductor layer of a type different from the first semiconductor layer 21. For example, the second semiconductor layer 23 may include at least one p-type semiconductor layer. For example, the second semiconductor layer 23 may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or p-type dopant) such as magnesium (Mg), zinc (Zn), calcium (Ca), strontium (Sr), barium (Ba), or the like. However, the material for forming the second semiconductor layer 23 is not limited to the aforementioned example, and various other materials may be used to form the second semiconductor layer 23. In an embodiment of the disclosure, the second semiconductor layer 23 may include gallium nitride (GaN) semiconductor material doped with a second conductive dopant (or a p-type dopant).

The first light-emitting-element connection electrode ECE1 may be electrically connected to the second semiconductor layer 23. The first light-emitting-element connection electrode ECE1 may be connected to the first bonding electrode BE1.

The auxiliary layer 25 may include an undoped semiconductor material. For example, the auxiliary layer 25 may include an undoped gallium nitride (GaN) semiconductor material. The auxiliary layer 25 along with the first semiconductor layer 21 may form an n-type semiconductor layer.

In an embodiment, an example is illustrated where the first to third light emitting elements LD1 to LD3 include the auxiliary layer 25, but the disclosure is not limited thereto. For example, the first to third light emitting elements LD1 to LD3 may not include the auxiliary layer 25.

The first light emitting element LD1 may further include an insulating layer 26 provided to cover an outer circumferential surface of the vertical emission stack. The insulating layer 26 may prevent the active layer 22 from short-circuiting due to contact with other conductive material other than the first and second semiconductor layers 21 and 23. The insulating layer 26 may include transparent insulating material. The insulating layer 26 may be configured such that a lower surface of the first light-emitting-element connection electrode ECE1, which is opposite to the second semiconductor layer 23, is exposed. Furthermore, the insulating layer 26 may be configured such that an upper surface of the auxiliary layer 25, which contacts the cathode electrode CE, is exposed.

The lower surface of the first light-emitting-element connection electrode ECE1 may be connected to the first anode electrode AE1. The upper surface of the auxiliary layer 25 may be connected to the cathode electrode CE. Consequently, the first light emitting element LD1 may be electrically connected between the first anode electrode AE1 and the cathode electrode CE.

In embodiments, a reflective electrode may be disposed between the first light-emitting-element connection electrode ECE1 and the second semiconductor layer 23. Light emitted from the first light emitting element LD1 may be efficiently outputted toward the light functional layer LFL. The reflective electrode may be formed of conductive material having a certain reflectivity. The conductive material may include opaque metal. For example, the opaque metal may include metal such as silver (Ag), magnesium (Mg), aluminum (Al), platinum (Pt), palladium (Pd), gold (Au), nickel (Ni), neodymium (Nd), iridium (Ir), chrome (Cr), titanium (Ti), and an alloy thereof. However, the material of the reflective electrode is not limited to the aforementioned examples.

Each of the second and third light emitting elements LD2 and LD3 may be configured in the same manner as the first light emitting element LD1. Hereinafter, repetitive explanations will be omitted.

The overcoat layer OCL may be disposed in the first openings OP1 in which the first to third light emitting elements LD1 to LD3 are disposed. The overcoat layer OCL may secure the first to third light emitting elements LD1 to LD3 in place to prevent the first to third light emitting elements LD1 to LD3 from moving. Furthermore, the overcoat layer OCL may protect components disposed thereunder from foreign substances such as dust and water. For example, the overcoat layer OCL may include at least one of an inorganic insulating layer and an organic insulating layer. For example, the overcoat layer OCL may include epoxy, but embodiments are not limited thereto.

In embodiments, the overcoat layer OCL may not be provided on an upper surface LTS of each of the first to third light emitting elements LD1 to LD3. The first to third light emitting elements LD1 to LD3 may protrude into the light functional layer LFL. The first to third light emitting elements LD1 to LD3 may be at least partially positioned in second openings OP2 of a second bank BNK2. For example, a height of the upper surface LTS of each of the first to third light emitting elements LD1 to LD3 from the substrate SUB may be greater than that of a lowermost end RBE of a first reflective layer RFL1. Accordingly, light emitted from the first to third light emitting elements LD1 to LD3 may be provided to the light functional layer LFL at a relatively high rate.

The cathode electrode CE may be disposed on the first to third light emitting elements LD1 to LD3. The cathode electrode CE may be disposed over the overall areas of the first bank BNK1, the first to third light emitting elements LD1 to LD3, and the overcoat layer OCL. The cathode electrode CE may contact the auxiliary layer 25 of each of the first to third light emitting elements LD1 to LD3. The cathode electrode CE may be electrically connected to the second power voltage node VSSN of FIG. 2. A second power voltage applied to the second power voltage node VSSN may be transmitted to the first to third light emitting elements LD1 to LD3 through the cathode electrode CE.

The cathode electrode CE may be configured to be substantially transparent or translucent to meet a certain light transmittance. In embodiments, the cathode electrodes CE may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the cathode electrode CE is not limited to the foregoing examples.

The capping layer CPL may be disposed on the cathode electrode CE. The capping layer CPL may protect components disposed under the capping layer CPL such as the cathode electrode CE, and the first to third light emitting elements LD1 to LD3 from external water, moisture, or the like. The capping layer CPL may include at least one of silicon nitride (SiNₓ), silicon oxide (SiOₓ), silicon oxynitride (SiOₓN_{y}), and metal oxide such as aluminum oxide (AlOₓ). However, the material of the capping layer CPL may not be limited to the aforementioned examples.

The light functional layer LFL may be disposed on the capping layer CPL. The light functional layer LFL may include the second bank BNK2, the first reflective layer RFL1, a third passivation layer PSV3, first and second light conversion patterns CCP1 and CCP2, a light scattering pattern LSP, a low refractive layer LRL, and a color filter layer CFL.

The second bank BNK2 may be disposed on the capping layer CPL. The second bank BNK2 may overlap the first bank BNK1. The second bank BNK2 may have the second openings OP2 that overlap the first openings OP1.

The second bank BNK2 may include light blocking material, thus preventing light mixing between adjacent pixels and the first to third sub-pixels SP1 to SP3. In embodiments, the second bank BNK2 may include organic material. For example, the second bank BNK2 may include organic insulating material made of material such as acryl resin, epoxy resin, phenol resin, polyamide resin, polyimide resin, or the like.

The first reflective layer RFL1 may be disposed on side surfaces of the second bank BNK2 adjacent to the second openings OP2. The first reflective layer RFL1 may be configured to reflect incident light, thus enhancing the light output efficiency. The first reflective layer RFL1 may include material suitable for reflecting light. The first reflective layer RFL1 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from among the aforementioned materials. However, the embodiments are not limited to the aforementioned examples.

It can be understood that an emission area EMA and a non-emission area NEMA for each of the first to third sub-pixels SP1 to SP3 are defined by the second bank BNK2. An area overlapping the second bank BNK2 may correspond to the non-emission area NEMA. An area overlapping the second openings OP2 of the second bank BNK2 may correspond to the emission area EMA.

The third passivation layer PSV3 may be disposed on the capping layer CPL in the second openings OP2. The third passivation layer PSV3 may protect components disposed thereunder and provide an even upper surface. The third passivation layers PSV3 may include the same material as any of the first and second passivation layers PSV1 and PSV2, but the embodiments are not limited thereto.

The first and second light conversion patterns CCP1 and CCP2 and the light scattering pattern LSP may be disposed on the third passivation layer PSV3 in the second openings OP2.

The first and second light conversion patterns CCP1 and CCP2 and the light scattering pattern LSP may include color conversion particles and/or scattering particles. The color conversion particles may change the wavelength of incident light and convert the incident light into light in a different color. Furthermore, the color conversion particles may scatter the incident light. In embodiments, the color conversion particles may be quantum dots. The scattering particles may scatter incident light.

In embodiments, the first to third light emitting elements LD1 to LD3 may be configured to emit light in blue. The first light conversion pattern CCP1 may include first color conversion particles QD1 configured to convert light in blue into light in red. The second light conversion pattern CCP2 may include second color conversion particles QD2 configured to convert light in blue into light in green. The light scattering pattern LSP may include scattering particles SCT for scattering light in blue to enhance the light output efficiency. Accordingly, the first to third sub-pixels SP1 to SP3 may be provided as a red sub-pixel, a green sub-pixel, and a blue sub-pixel, respectively. In embodiments, at least one of the first and second light conversion patterns CCP1 and CCP2 and the light scattering pattern LSP may further include color conversion particles provided to convert light in blue into light in white.

In embodiments, the first to third light emitting elements LD1 to LD3 may be configured to emit light in red, green, and blue, respectively. Each of the first and second light conversion patterns CCP1 and CCP2 and the light scattering pattern LSP may include scattering particles SCT. As such, particles included in the first and second light conversion patterns CCP1 and CCP2 and the light scattering pattern LSP may be changed in various ways depending on the first to third light emitting elements LD1 to LD3.

In embodiments, the first and second light conversion patterns CCP1 and CCP2 and the light scattering pattern LSP may be omitted.

The low refractive layer LRL may be disposed on the second bank BNK2, the first reflective layer RFL1, the first and second light conversion patterns CCP1 and CCP2, and the light scattering pattern LSP. The low refractive layer LRL may have a refractive index lower than the first and second light conversion patterns CCP1 and CCP2 and the light scattering pattern LSP. The low refractive layer LRL is configured to refract or totally reflect incident light depending on an incident angle of the corresponding light. The low refractive layer LRL may provide the light that has passed through the first and second light conversion patterns CCP1 and CCP2 and the light scattering pattern LSP back to the first and second light conversion patterns CCP1 and CCP2 and the light scattering pattern LSP. Accordingly, the first and second light conversion patterns CCP1 and CCP2 and the light scattering pattern LSP may be enhanced in light conversion efficiency and light scattering efficiency. In embodiments, the low refractive layer LRL may be omitted in an area corresponding to the third sub-pixel SP3.

The color filter layer CFL may be disposed on the low refractive layer LRL. The color filter layer CFL may include first to third color filters CF1 to CF3 and light blocking patterns LBP.

The first to third color filters CF1 to CF3 may respectively overlap the first and second light conversion patterns CCP1 and CCP2 and the light scattering pattern LSP. Each of the first to third color filters CF1 to CF3 may allow light in a desired wavelength range to selectively pass through the color filter. In the case where the first sub-pixel SPX1 is a red sub-pixel, the first color filter CF1 may include a red color filter. In the case where the second sub-pixel SPX2 is a green sub-pixel, the second color filter CF2 may include a green color filter. In the case where the third sub-pixel SP3 is a blue sub-pixel, the third color filter CF3 may include a blue color filter. Each of the first to third color filters CF1 to CF3 may have a refractive index higher than the low refractive layer LRL. However, the embodiments are not limited to the aforementioned example, each of the first to third color filters CF1 to CF3 may have a refractive index equal to or lower than the low refractive layer LRL.

The light blocking patterns LBP may be disposed between the first to third color filters CF1 to CF3. It can be understood that the emission area (or light output area) EMA and the non-emission area NEMA for each of the first to third sub-pixels SP1 to SP3 are defined by the light blocking patterns LBP. An area overlapping the light blocking patterns LBP may correspond to the non-emission area NEMA. An area that does not overlap the light blocking patterns LBP may correspond to the emission area EMA.

In embodiments, the light blocking patterns LBP may include at least one of various kinds of light blocking materials. In embodiments, each of the light blocking patterns LBP may be provided in the form of a multilayer structure in which at least two color filters of the first to third color filters CF1 to CF3 overlap each other. For example, each of the light blocking patterns LBP may be formed by overlapping the first to third color filters CF1 to CF3. As another example, a light blocking pattern between the first and second color filters CF1 and CF2 among the light blocking patterns LBP may be formed of a multilayer structure in which the first and second color filters CF1 and CF2 overlap each other. A light blocking pattern between the second and third color filters CF2 and CF3 among the light blocking patterns LBP may be formed of a multilayer structure in which the second and third color filters CF2 and CF3 overlap each other. A light blocking pattern between the first color filter CF1 and a third color filter CF3 of a neighboring pixel may be formed of a multilayer structure in which the first and third color filters CF1 and CF3 overlap each other. As such, each of the first to third color filters CF1 to CF3 may extend to the non-emission area NEMA, thus forming the light blocking patterns LBP.

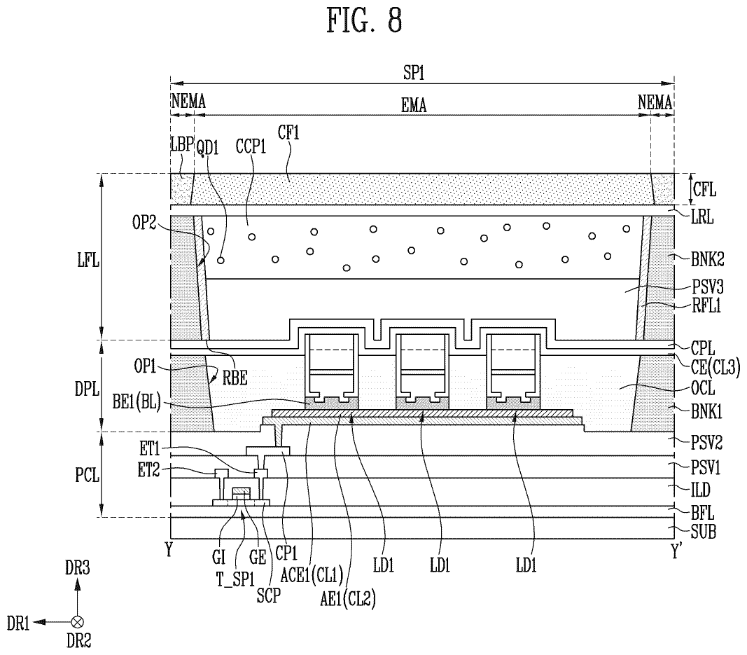

FIG. 8 is a schematic sectional view taken along line Y-Y′ of FIG. 6.

The pixel circuit layer PCL, the display element layer DPL, and the light functional layer LFL in FIG. 8 can be explained in the same manner as described with reference to FIG. 7; therefore, redundant explanations thereof will be omitted.

Referring to FIGS. 6 and 8, the pixel circuit layer PCL, the display element layer DPL, and the light functional layer LFL may be sequentially provided on the substrate SUB. Each first sub-pixel SP1 may include multiple first light emitting elements LD1. For example, the light emitting elements LD1 may be disposed on the first anode electrode AE1. The first light emitting elements LD1 may be electrically connected to the same first anode electrode AE1.

The second electrode layer CL2 (i.e., the first anode electrode AE1) may be exposed between the first light emitting elements LD1. The exposed second electrode layer CL2 may reflect light emitted from the first light emitting elements LD1. In other words, since the second electrode layer CL2 between the first light emitting elements LD1 is exposed, the amount of light reflected by the second electrode layer CL2 may increase.

Although FIG. 8 illustrates only the first sub-pixel SP1, each of the second and third sub-pixels SP2 and SP3 (refer to FIG. 7) may be configured in the same manner as the first sub-pixel SP1. Hereinafter, repetitive explanations will be omitted.

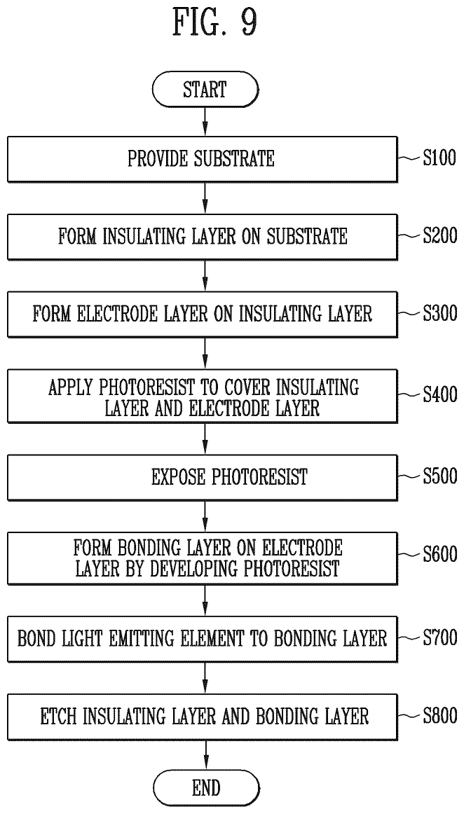

FIG. 9 is a schematic flowchart illustrating a method of fabricating the display device in accordance with embodiments of the disclosure.

Referring to FIG. 9, the method of fabricating the display device may include step S100 of providing a substrate, step S200 of forming an insulating layer on the substrate, step S300 of forming an electrode layer on the insulating layer, step S400 of applying photoresist to cover the insulating layer and the electrode layer, step S500 of exposing the photoresist, step S600 of forming a bonding layer on the electrode layer by developing the photoresist, step S700 of bonding a light emitting element to the bonding layer, and step S800 of etching the insulating layer and the bonding layer.

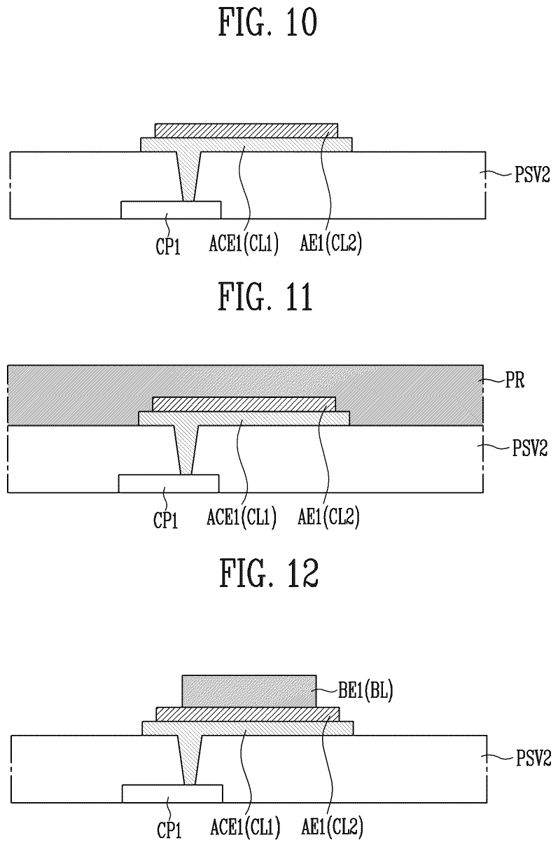

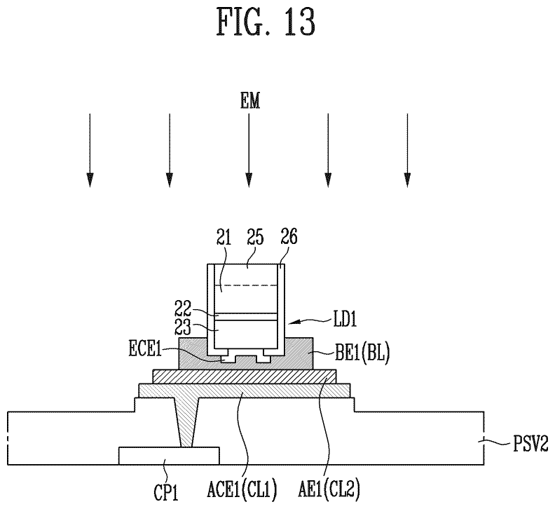

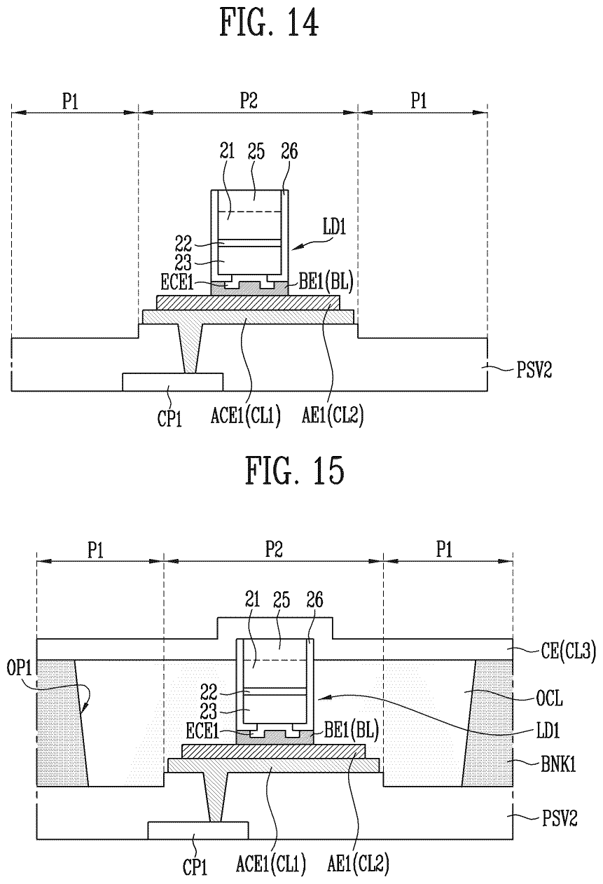

Hereinafter, the method will be described in detail with reference to FIGS. 10 to 15.

FIGS. 10 to 15 are schematic views for describing the display device fabrication method of FIG. 9.

The components in FIGS. 10 to 15 are the same as the components of the display device described with reference to FIGS. 1 to 8; therefore, redundant explanations thereof will be omitted.

Referring to FIGS. 7 and 10, the second passivation layer PSV2 may be formed on the substrate SUB. The first and second electrode layers CL1 and CL2 may be formed on the second passivation layer PSV2.

Referring to FIGS. 7 and 11, the photoresist PR may be applied to cover the second passivation layer PSV2 and the second electrode layer CL2. The photoresist PR may include conductive material. For example, the photoresist PR may include carbon black.

Referring to FIGS. 7 and 12, the bonding layer BL may be formed on the second electrode layer CL2 by exposing and developing the photoresist PR. In other words, the bonding layer BL may be a portion of the photoresist PR (refer to FIG. 11) that remains after the exposure and development.

Referring to FIGS. 7, 13, and 14, the first light emitting element LD1 may be bonded to the first bonding electrode BE1. For example, the first light emitting element LD1 may be coupled to the first bonding electrode BE1 by applying pressure, and the first bonding electrode BE1, with the first light emitting element LD1 coupled thereto, may be cured through a curing process.

The second passivation layer PSV2 and the bonding layer BL may be etched. In an embodiment, the second passivation layer PSV2 and the bonding layer BL may be etched through a dry etching process. For example, an etching material EM may be sprayed onto the overall area of the substrate SUB. The exposed second passivation layer PSV2 and the exposed bonding layer BL may be etched using the first to third light emitting elements LD1 to LD3 as a mask. Consequently, a height of an exposed first portion P1 of the second passivation layer PSV2 may be less than that of an unexposed second portion P2 of the second passivation layer PSV2. Furthermore, as illustrated in FIG. 8, the bonding layer BL between the first light emitting elements LD1 may be etched.

At steps S400, S500, and S600 described with reference to FIGS. 11 and 12, a portion of the photoresist PR may remain on the exposed second passivation layer PSV2. The remaining portion of the photoresist PR may cause a short circuit between the adjacent first to third light emitting elements LD1 to LD3. However, the remaining portion of the photoresist PR may be removed by etching the exposed second passivation layer PSV2. Furthermore, as illustrated in FIG. 8, the bonding layer BL between the first light emitting elements LD1 may be etched to expose the first anode electrode AE1. Therefore, light emitted from the first light emitting elements LD1 may be reflected by the exposed first anode electrode AE1.

The first light emitting element LD1 may include the auxiliary layer 25. The auxiliary layer 25 may prevent the first light emitting element LD1 from being damaged by the etching material. However, the disclosure is not limited to the aforementioned example. For example, the first light emitting element LD1 may not include the auxiliary layer 25.

Referring to FIGS. 7 and 15, the first bank BNK1 may be formed on the second passivation layer PSV2, and the overcoat layer OCL may be formed in the first opening OP1. The third electrode layer CL3 may be formed to cover the first bank BNK1, the overcoat layer OCL, and the first light emitting element LD1.

Although FIGS. 10 to 15 illustrate only the first sub-pixel SP1, each of the second and third sub-pixels SP2 and SP3 may be configured in the same manner as the first sub-pixel SP1. Hereinafter, repetitive explanations will be omitted.

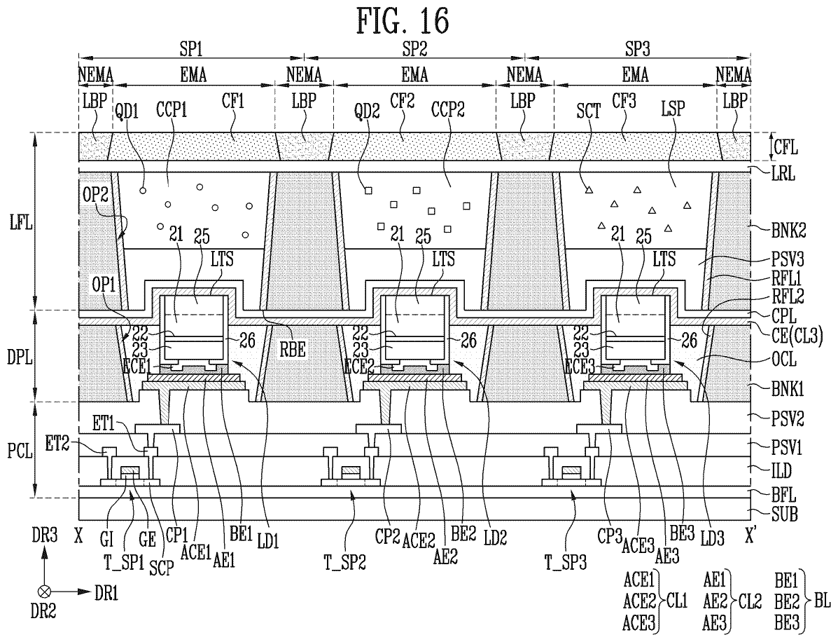

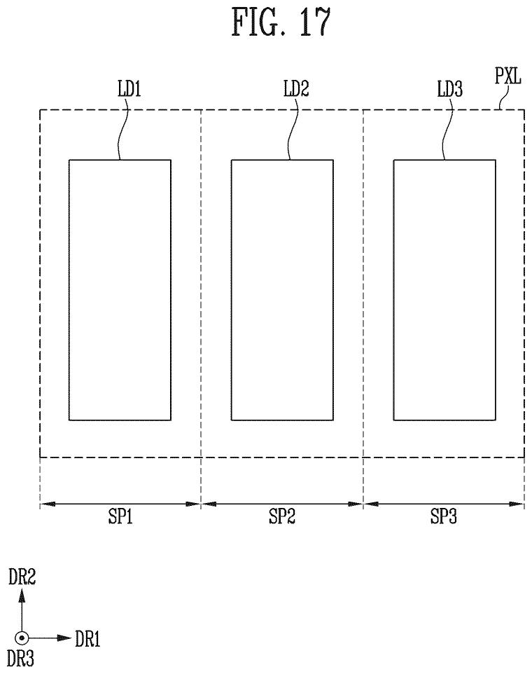

FIG. 16 is a schematic view illustrating another embodiment of a sectional view taken along line X-X′ of FIG. 6.

The configuration of the display device in accordance with the embodiments may be substantially the same as that of the display device of FIG. 7, other than a second reflective layer RFL2; therefore, identical or similar components are denoted by the same reference numerals and symbols, and redundant explanation thereof will be omitted.

Referring to FIG. 16, the second reflective layer RFL2 may be formed on a side surface of the first bank BNK1. The second reflective layer RFL2 may include conductive materials suitable for reflecting light. Consequently, the light output efficiency of the first light emitting element LD1 may be enhanced. In embodiments, the second reflective layer RFL2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from among the aforementioned materials. However, the embodiments are not limited to the aforementioned examples.

FIG. 17 is a schematic plan view illustrating another embodiment of any one of the pixels of FIG. 3.

The configuration of the pixel in accordance with an embodiment may be substantially the same as that of the pixel of FIG. 6, other than first to third light emitting elements LD1 to LD3; therefore, identical or similar components are denoted by the same reference numerals and symbols, and redundant explanation thereof will be omitted.

Referring to FIG. 17, a first light emitting element LD1, a second light emitting element LD2, and a third light emitting element LD3 may be disposed on the first to third anode electrodes. The first light emitting element LD1 may be connected to the first anode electrode. The first light emitting element LD2 may be connected to the second anode electrode. The third light emitting element LD3 may be connected to the third anode electrode. The first to third anode electrodes may be disposed substantially the same as illustrated in FIG. 6.

The first light emitting element LD1 may be provided as the light emitting element LD of FIG. 2 included in the first sub-pixel SP1. The second light emitting element LD2 may be provided as the light emitting element LD of FIG. 2 included in the second sub-pixel SP2. The third light emitting element LD3 may be provided as the light emitting element LD of FIG. 2 included in the third sub-pixel SP3.

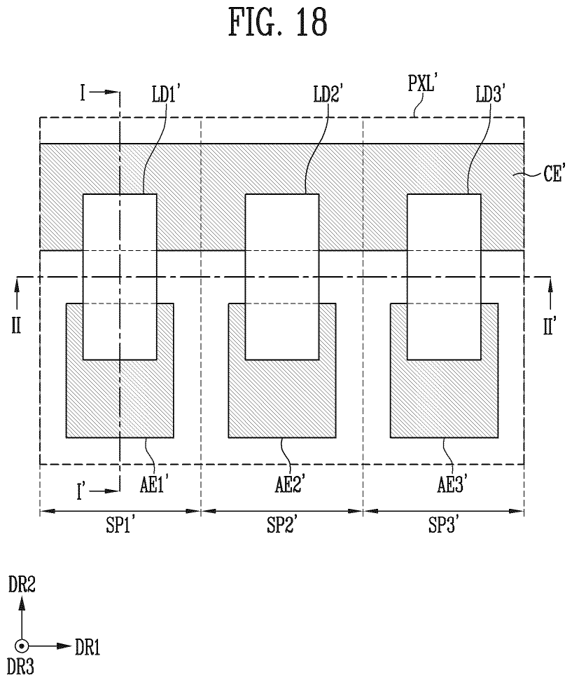

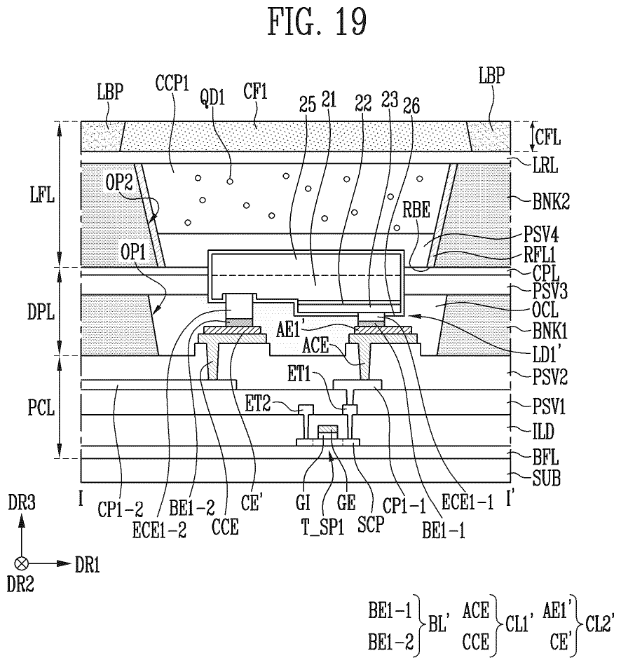

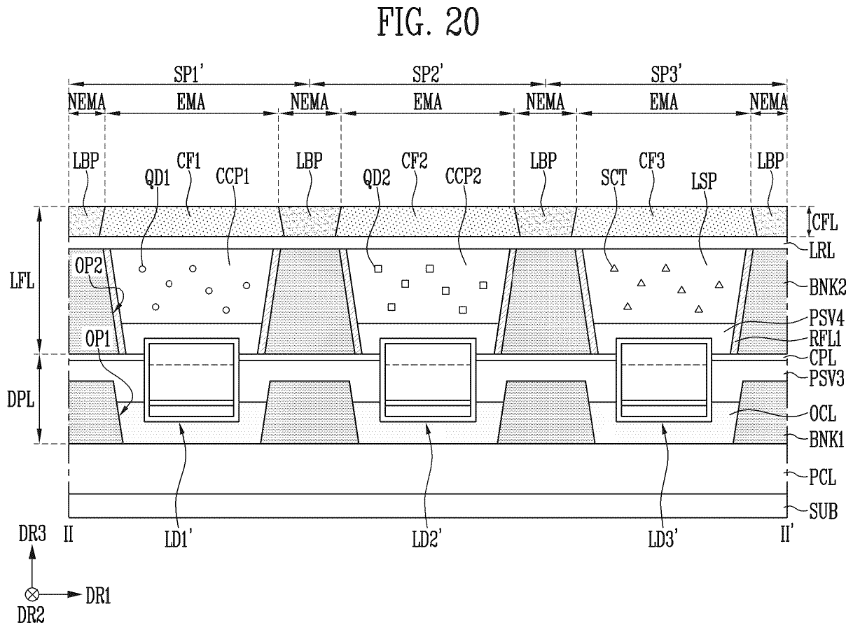

FIG. 18 is a schematic plan view illustrating an embodiment of any one of the pixels of the display device in accordance with embodiments of the disclosure. FIG. 19 is a schematic sectional view taken along line I-I′ of FIG. 18. FIG. 20 is a schematic sectional view taken along line II-II′ of FIG. 18.

The configuration of the display device in accordance with an embodiment may be substantially the same as that of the display device of FIGS. 6 and 7, other than a display element layer DPL; therefore, identical or similar components are denoted by the same reference numerals and symbols, and redundant explanation thereof will be omitted.

Referring to FIG. 18, a pixel PXL' may include first to third sub-pixels SP1′ to SP3′. The first to third sub-pixels SP1′ to SP3′ may be arranged in the first direction DR1. However, the arrangement of the pixel PXL′ is not limited thereto, and may be changed in various ways depending on the embodiments. For example, the first to third sub-pixels SP1′ to SP3′ may be arranged in a zigzag pattern.

First to third anode electrodes AE1′ to AE3′ may be respectively disposed in the first to third sub-pixels SP1′ to SP3′. The first anode electrode AE1′ may be provided as the anode electrode AE (refer to FIG. 2) connected to the sub-pixel circuit SPC (refer to FIG. 2) of the first sub-pixel SP1′. The second anode electrode AE2′ may be provided as the anode electrode AE connected to the sub-pixel circuit SPC of the second sub-pixel SP2′. The third anode electrode AE3′ may be provided as the anode electrode AE connected to the sub-pixel circuit SPC of the third sub-pixel SP3′.

A cathode electrode CE′ may be spaced apart from the first to third anode electrodes AE1′ to AE3′. The cathode electrode CE′ may be disposed at the same height as the first to third anode electrodes AE1′ to AE3′. The cathode electrode CE′ may be spaced apart from the first to third anode electrodes AE1′ to AE3′ in the second direction DR2. In embodiments, the cathode electrode CE′ may extend in the first direction DR1, and may be used as a common electrode for the pixel PXL′ and other pixels adjacent to the pixel PXL′. Although not illustrated, the cathode electrode CE′ may extend not only in the first direction DR1 but also in the second direction DR2, and may thus be used as a common electrode for all of the sub-pixels SP of FIG. 3. As such, the cathode electrode CE′ may have various shapes.

The first to third light emitting elements LD1′ to LD3′ may be disposed on the first to third anode electrodes AE1′ to AE3′ and the cathode electrode CE′. The first light emitting element LD1′ may be electrically connected to the first anode electrode AE1′ and the cathode electrode CE′. The first light emitting element LD1′ may be provided as the light emitting element LD (refer to FIG. 2) connected to the sub-pixel circuit SPC of the first sub-pixel SP1′. The second light emitting element LD2′ may be electrically connected to the second anode electrode AE2′ and the cathode electrode CE′. The second light emitting element LD2′ may be provided as a light emitting element LD connected to the sub-pixel circuit SPC of the second sub-pixel SP2′. The third light emitting element LD3′ may be electrically connected to the third anode electrode AE3′ and the cathode electrode CE′. The third light emitting element LD3′ may be provided as a light emitting element LD connected to the sub-pixel circuit SPC of the third sub-pixel SP3′.

Referring to FIGS. 18 and 19, the pixel circuit layer PCL, the display element layer DPL, and the light functional layer LFL may be sequentially disposed on the substrate SUB.

The display element layer DPL may be disposed on the second passivation layer PSV2. The display element layer DPL may include a first electrode layer CL1′, a second electrode layer CL2′, a bonding layer BL′, a first bank BNK1, the first to third light emitting elements LD1′ to LD3′, an overcoat layer OCL, and a capping layer CPL. The first electrode layer CL1′ may include an anode connection electrode ACE and a cathode connection electrode CCE. The second electrode layer CL2′ may include the first anode electrode AE1′ and the cathode electrode CE′. The bonding layer BL′ may include 1-1-th and 1-2-th bonding electrodes BE1-1 to BE1-2.

The first anode electrode AE1′ and the cathode electrode CE′ may be disposed on the pixel circuit layer PCL.

The anode connection electrode ACE may be electrically connected to a 1-1-th connection pattern CP1-1 through a contact hole passing through the second passivation layer PSV2. The 1-1-th connection pattern CP1-1 may be electrically connected to the first transistor T_SP1. The first anode electrode AE1′ may be electrically connected to the anode connection electrode ACE. As such, the first anode electrode AE1′ may be electrically connected to the first transistor T_SP1.

The cathode electrode CE′ may be spaced apart from the first anode electrode AE1′ in the first direction DR1. The cathode electrode CE′ may be electrically connected to the cathode connection electrode CCE. The cathode connection electrode CCE may be electrically connected to a 1-2-th connection pattern CP1-2 through a contact hole passing through the second passivation layer PSV2. Th 1-2-th connection pattern CP1-2 may be the second power voltage node VSSN in FIG. 2, or may be electrically connected to the second power voltage node VSSN. Accordingly, a second power voltage applied to the second power voltage node VSSN may be transmitted to the cathode electrode CE′.

In an embodiment, an example is described where the cathode electrode CE′ is connected to the second power voltage node VSSN through the 1-2-th connection pattern CP1-2, but the disclosure is not limited hereto. For example, the cathode electrode CE′ may extend onto the first bank BNK1 and be connected to the second power voltage node VSSN or electrically connected to a conductive pattern formed on the first bank BNK1.

The first bank BNK1 may be disposed on the second passivation layer PSV2. The first bank BNK1 may include a first opening OP1 through which at least portions of the first anode electrode AE1′ and the cathode electrode CE′ are exposed. The first light emitting element LD1′ may be disposed in the first opening OP1 of the first bank BNK1. As such, the first bank BNK1 may be provided as a pixel defining layer that defines an area where the first light emitting element LD1′ is positioned.

The first light emitting element LD1′ may be disposed on the first anode electrode AE1′ and the cathode electrode CE′. The 1-1-th bonding electrode BE1-1 may be disposed on the first anode electrode AE1′. The 1-2-th bonding electrode BE1-2 may be disposed on the cathode electrode CE′. The first light emitting element LD1′ may be bonded to the 1-1-th and 1-2-th bonding electrodes BE1-1 and BE1-2 and thus be electrically connected to the first anode electrode AE1′.

The first light emitting element LD1′ may include a 1-1-th light-emitting-element connection electrode ECE1-1, a 1-2-th light-emitting-element connection electrode ECE1-2, a first semiconductor layer 21, an active layer 22, a second semiconductor layer 23, and an auxiliary layer 25. The first light emitting element LD1′ may be implemented as a vertical emission stack in which the first light-emitting-element connection electrode ECE1, the second semiconductor layer 23, the active layer 22, the first semiconductor layer 21, and the auxiliary layer 25 are stacked on each other in the third direction DR3.

The first light emitting element LD1′ may be electrically connected to the first anode electrode AE1′ through the 1-1-th light-emitting-element connection electrode ECE1-1. The first light emitting element LD1′ may be electrically connected to the cathode electrode CE′ through the 1-2-th light-emitting-element connection electrode ECE1-2. The first light emitting element LD1′ may be bonded and coupled to the 1-1-th and 1-2-th light-emitting-element connection electrodes ECE1-1 and ECE1-2.

The third passivation layer PSV3 may be disposed on the first bank BNK1 and the overcoat layer OCL. The third passivation layer PSV3 may protect components disposed thereunder and provide an even upper surface. The third passivation layers PSV3 may include the same material as any of the first and second passivation layers PSV1 and PSV2, but the embodiments are not limited thereto.

In embodiments, the third passivation layer PSV3 may not be disposed on an upper surface LTS of the first light emitting element LD1′. The first light emitting element LD1′ may protrude into the light functional layer LFL. The first light emitting element LD1′ may be positioned at least partially in the second opening OP2 of the second bank BNK2. For example, a height of the upper surface LTS of the first light emitting element LD1′ from the substrate SUB may be greater than that of the lowermost end RBE of the reflective layer RFL. Accordingly, light emitted from the first light emitting element LD1′ may be provided to the light functional layer LFL at a relatively high rate.

The capping layer CPL may be disposed on the third passivation layer PSV3. The capping layer CPL may protect components disposed under the capping layer CPL such as the first light emitting element LD1′ from external water, moisture, or the like. In embodiments, the capping layer CPL may not be disposed on the upper surface of the first light emitting element LD1′. In other embodiments, the capping layer CPL may cover overall surfaces of the first light emitting element LD1′ and the third passivation layer PSV3. The capping layer CPL may include at least one of silicon nitride (SiNₓ), silicon oxide (SiOₓ), silicon oxynitride (SiOₓN_{y}), and metal oxide such as aluminum oxide (AlOₓ). However, the material of the capping layer CPL may not be limited to the aforementioned examples.

Hitherto, the display element layer DPL of the first sub-pixel SP1′ has been described. Each of the second and third sub-pixels SP2′ and SP3′ of FIG. 18 may also be configured in the same manner as the first sub-pixel SP1′ unless otherwise described.

Referring to FIGS. 18 and 20, the pixel circuit layer PCL, the display element layer DPL, and the light functional layer LFL may be sequentially provided on the substrate SUB.

The display element layer DPL may be described in the same manner as described with reference to FIG. 19. Sub-pixel circuits respectively corresponding to the first to third sub-pixels SP1′ to SP3′ may be provided in the pixel circuit layer PCL. The first to third light emitting elements LD1′ to LD3′ respectively corresponding to the first to third sub-pixels SP1′ to SP3′ may be provided in the display element layer DPL. The first to third light emitting elements LD1′ to LD3′ may overlap the first openings OP1 of the first bank BNK1. The first light emitting elements LD1′ may be connected between the cathode electrode CE′ (refer to FIG. 19) and the transistor T_SP1′ (refer to FIG. 19) included in the sub-pixel circuit of the first sub-pixel SP1′. The second light emitting element LD2′ may be connected between the cathode electrode CE′ and the transistor included in the sub-pixel circuit of the second sub-pixel SP2′. The third light emitting element LD3′ may be connected between the cathode electrode CE′ and the transistor included in the sub-pixel circuit of the third sub-pixel SP3′. Hereinafter, repetitive explanations will be omitted.

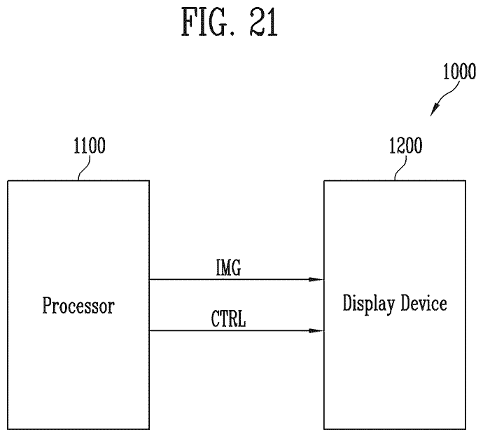

FIG. 21 is a schematic block diagram illustrating an embodiment of a display system 1000.

Referring to FIG. 21, the display system 1000 may include a processor 1100 and a display device 1200.

The processor 1100 may perform various tasks and operations. In embodiments, the processor 1100 may include an application processor, a graphic processor, a microprocessor, a central processing unit (CPU), and so on. The processor 1100 may be connected to other components of the display system 1000 through a bus system to control the components.

The processor 1100 may transmit image data IMG and a control signal CTRL to the display device 1200. The display device 1200 may display an image based on the image data IMG and the control signal CTRL. The display device 1200 may be configured in the same manner as the display device DD described with reference to FIG. 1. The image data IMG and the control signal CTRL may be respectively provided as the input image data IMG and the control signal CTRL of FIG. 1.

The display system 1000 may include computing systems that provide an image display function, such as a smart watch, a mobile phone, a smart phone, a portable computer, a tablet personal computer (tablet PC), a watch phone, an automotive display, smart glasses, a portable multimedia player (PMP), a navigation system, and an ultra mobile personal computer (UMPC). Furthermore, the display system 1000 may include at least one of a head-mounted display (HMD), a virtual reality (VR) device, a mixed reality (MR) device, and an augmented reality (AR) device.

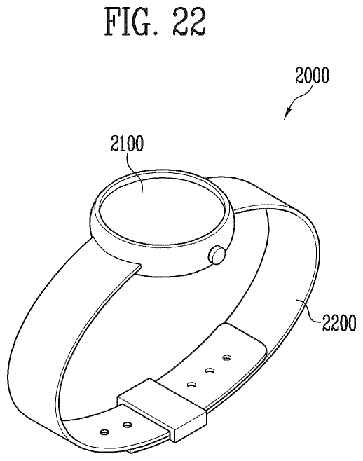

FIGS. 22 to 25 are schematic perspective views illustrating application examples of the display system 1000 of FIG. 21.

Referring to FIG. 22, the display system 1000 of FIG. 21 may be applied to a smart watch 2000 including a display component 2100 and a strap 2200.

The smart watch 2000 may be a wearable electronic device. For example, the smart watch 2000 may have a structure in which the strap 2200 may be mounted on the wrist of the user. Here, the display system 1000 and/or the display device 1200 may be applied to the display component 2100, so that image data including time information can be provided to the user.

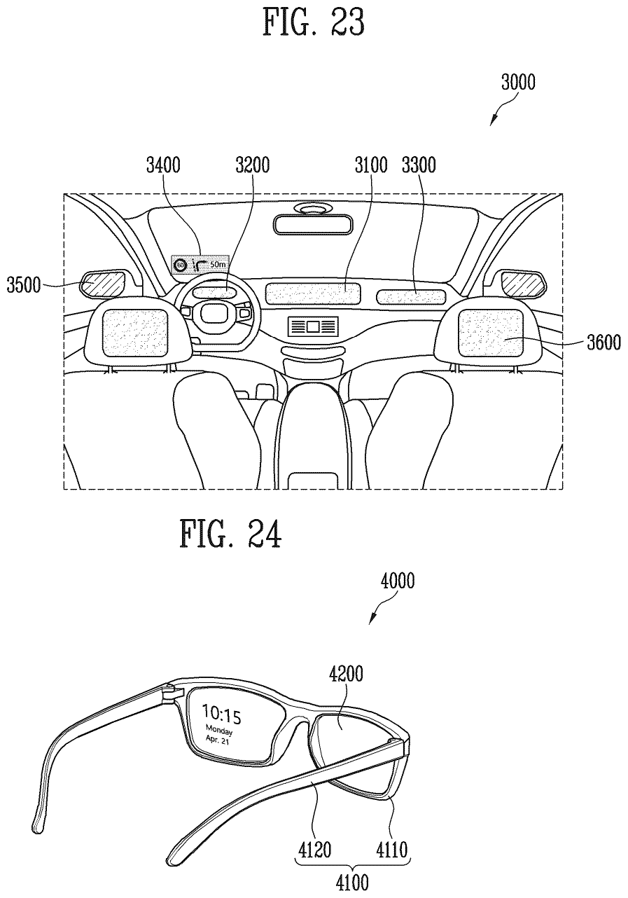

Referring to FIG. 23, the display system 1000 of FIG. 21 may be applied to the automotive display system 3000. Here, the automotive display system 3000 may include a computing system that is provided inside and/or outside a vehicle to provide image data.

For example, the display system 1000 and/or the display device 1200 may be applied to at least any one of an infotainment panel 3100, a cluster 3200, a co-driver display 3300, a head-up display 3400, a side mirror display 3500, and a rear seat display 3600, which may be provided in the vehicle.

Referring to FIG. 24, the display system 1000 of FIG. 21 may be applied to smart glasses 4000. The smart glasses 4000 may be a wearable electronic device capable of being worn on the head of the user. For example, the smart glasses 4000 may be a wearable device for augmented reality.

The smart glasses 4000 may include a frame 4100 and a lens component 4200. The frame 4100 may include a housing 4110 which supports the lens component 4200, and a leg component 4120 enabling the user to wear the smart glasses. The leg component 4120 may be connected to the housing 4110 by a hinge, and thus can be folded or unfolded with respect to the housing 4110.

The frame 4100 may be equipped with a battery, a touch pad, a microphone, a camera, and the like. Furthermore, the frame 4100 may be equipped with a projector configured to output light, and a processor configured to control a light signal and the like.

The lens component 4200 may include an optical component configured to transmit or reflect light. For example, the lens component 4200 may include glass, transparent synthetic resin, and the like.

To enable the eyes of the user to perceive visual information, the lens component 4200 may reflect images based on an optical signal transmitted from the projector of the frame 4100 by a rear surface of the lens component 4200 (e.g., a surface facing the eyes of the user). For example, the user may perceive visual information such as time and date displayed on the lens component 4200. Here, the projector and/or the lens component 4200 may be a kind of display device. The display device 1200 may be applied to the projector and/or the lens component 4200.

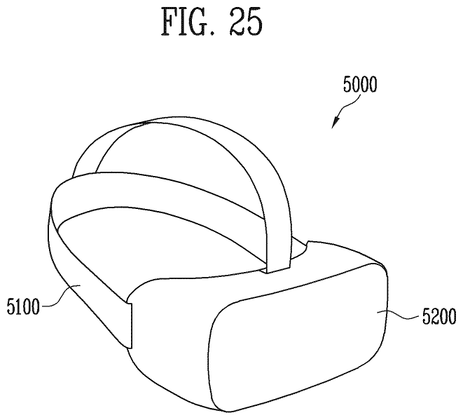

Referring to FIG. 25, the display system 1000 of FIG. 21 may be applied to a head-mounted display device 5000.

The head-mounted display device 5000 may be a wearable electronic device, which can be worn on the head of the user. For example, the head-mounted display device 5000 may be a wearable device for virtual reality or mixed reality.

The head-mounted display 5000 may include a head-mounted band 5100 and a display device reception casing 5200. The head-mounted band 5100 may be connected to the display device reception casing 5200. The head-mounted band 5100 may include a horizontal band and/or a vertical band to fasten the head-mounted display 5000 to the head of the user. The horizontal band may enclose the sides of the head of the user, and the vertical band may enclose the top of the head of the user. However, embodiments are not limited to the aforementioned example. For example, the head-mounted band 5100 may be implemented in the form of eyeglass frames, a helmet, and so on.

The display device reception casing 5200 may receive the display system 1000 and/or the display device 1200.

In a method of fabricating a display device in accordance with embodiments of the disclosure, an insulating layer exposed during a process of applying photoresist may be etched, thereby preventing a short circuit between light emitting elements from occurring due to residual photoresist.

In the method of fabricating a display device in accordance with embodiments of the disclosure, a bonding layer between light emitting elements may be etched to expose an anode electrode. Light emitted from the light emitting elements may be reflected by the exposed anode electrode. Consequently, the light output efficiency of the light emitting elements may be enhanced.

In the method of fabricating a display device in accordance with embodiments of the disclosure, a reflective layer may be formed on a first bank, whereby light emitted from the light emitting elements may be reflected. Accordingly, the light output efficiency of the light emitting elements may be enhanced.

However, effects of the disclosure are not limited to the above- described effects, and various modifications are possible without departing from the spirit and scope of the disclosure.

Although certain embodiments and implementations have been described herein, this is only provided for the sake of more general understanding of the disclosure, and those skilled in the art will appreciate that the disclosure is not limited to the foregoing embodiments, and other modifications, additions and substitutions are possible.

Accordingly, the disclosure is not limited to such embodiments, but rather includes all such embodiments along with various modifications and equivalent arrangements thereof as would be apparent to a person of ordinary skill in the art.

The disclosure may be applied to a display device and an electronic device including the display device. For example, the disclosure may be applied to digital TVs, 3D TVs, cellular phones, smartphones, tablet computers, VR devices, PCs, home appliances, laptop computers, PDAS, portable media players (PMPs), digital cameras, music players, portable game consoles, navigation devices, and so on.

While embodiments have been described above, those skilled in the art will appreciate that various modifications, additions and substitutions are possible, without departing from the scope and spirit of the disclosure claimed in the appended claims.

What is claimed is:

1. A method of fabricating a display device, comprising:
providing a substrate;
forming an insulating layer on the substrate;
forming a first electrode layer on the insulating layer;
applying a photoresist to cover the insulating layer and the first electrode layer;
exposing the photoresist;
forming a bonding layer on the first electrode layer by developing the photoresist;
bonding a light emitting element to the bonding layer; and
etching the insulating layer.

2. The method according to claim 1, wherein the etching of the insulating layer is by dry etching.

3. The method according to claim 1, wherein the etching of the insulating layer is by spraying an etching material onto an overall area of the substrate.

4. The method according to claim 1, wherein the etching of the insulating layer comprises etching the bonding layer using the light emitting element as a mask.

5. The method according to claim 4, wherein
the bonding of the light emitting element to the bonding layer includes bonding a plurality of light emitting elements including the light emitting element to the bonding layer, and
the etching of the insulating layer comprises etching the bonding layer between the plurality of light emitting elements.

6. The method according to claim 1, wherein the photoresist includes a conductive material.

7. The method according to claim 6, wherein the photoresist includes carbon black.

8. The method according to claim 1, wherein the light emitting element further comprises:
a semiconductor layer; and
an auxiliary layer disposed on the semiconductor layer.

9. The method according to claim 8, wherein the auxiliary layer includes an undoped semiconductor material.

10. The method according to claim 1, wherein the first electrode layer includes at least one of aluminum (Al), silver (Ag), magnesium (Mg), platinum (Pt), palladium (Pd), gold (Au), nickel (Ni), neodymium (Nd), iridium (Ir), chromium (Cr), and titanium (Ti).

11. The method according to claim 1, further comprising forming a second electrode layer on the light emitting element.

12. The method according to claim 1, wherein the first electrode layer includes:
a first electrode connected to the light emitting element; and
a second electrode spaced apart from the first electrode.

13. The method according to claim 1, further comprising:
forming a bank on the insulating layer; and
forming a reflective layer on a side surface of the bank.

14. A method of fabricating a display device, comprising:
providing a substrate;
forming an insulating layer on the substrate;
forming an electrode layer on the insulating layer;
applying a photoresist to cover the insulating layer and the electrode layer;
exposing the photoresist;
forming a bonding layer on the electrode layer by developing the photoresist;
bonding light emitting elements to the bonding layer; and
etching the bonding layer between the light emitting elements.

15. The method according to claim 14, wherein the etching of the bonding layer is by dry etching.

16. The method according to claim 14, wherein the etching of the bonding layer is by spraying an etching material onto an overall area of the substrate.

17. The method according to claim 14, wherein the etching of the bonding layer is by using the light emitting elements as a mask.

18. The method according to claim 14, wherein the photoresist includes a conductive material.

19. A display device, comprising:
a substrate;
an insulating layer disposed on the substrate;
an overcoat layer disposed on a first portion of the insulating layer;
an electrode layer disposed on a second portion of the insulating layer;
a bonding layer disposed on the electrode layer; and
a light emitting element bonded to the bonding layer,
wherein a height of the first portion of the insulating layer is less than a height of the second portion of the insulating layer.

20. The display device according to claim 19, wherein
the light emitting element is one among a plurality of light emitting elements bonded to the bonding layer, and
the electrode layer is exposed between the light emitting elements.
